(19) United States
(12) Patent Application Publication
(10) Pub. No.: US 2026/0293760 A1
(43) Pub. Date: Sep. 24, 2026

(54) EMBEDDED LC MODULES FOR PACKAGED SEMICONDUCTOR DEVICES

(71) Applicant: Saras Micro Devices, Inc., Chandler, AZ (US)

(72) Inventor: Imran Khan, Alpharetta, GA (US)

(21) Appl. No.: 19/088,205

(22) Filed: Mar. 24, 2025

(51) Int. Cl. H10W 90/00; H01F 27/40; H10W 70/05; H10D 1/20; H10D 1/68

(52) U.S. Cl. CPC H10W 90/00; H01F 27/40; H10W 70/05; H10D 1/20; H10D 1/68

(57) ABSTRACT

Manufacturing a semiconductor device includes embedding an inductor and a capacitor (defining an LC module of a power converter) in a substrate core of a substrate, providing an input terminal of the LC module on a first side of the substrate core connected to an input of the inductor, providing an output terminal of the LC module on a second side of the substrate core connected to an output of the inductor and to an anode of the capacitor, providing a sense terminal on the first side of the substrate core connected to the output of the inductor and to the anode of the capacitor, and mounting an IC die on the substrate such that the LC module is in alignment with a power rail of the IC. The sense terminal may provide a feedback loop for regulating an output of a prior stage active component of the power converter.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

Power delivery and voltage regulation are mostly based on topologies where the inductor is the main element of energy storage (e.g., switching buck regulators). The inductor size, performance, and efficiency determine the overall performance of an integrated circuit (IC), especially for high-performance computing (HPC) applications. However, power delivery and voltage regulation are constrained by available layouts requiring connection to external devices. For example, the distance from the load and interconnect parasitics associated with conventional inductor placements limits the performance of ICs, especially for modern applications including HPC (e.g., data centers, artificial intelligence and deep learning, mobile computing platforms, GPUs, FPGA logic), analog and RF power and filter architectures, and electric vehicle power architectures.

Moreover, due to ongoing increases in processor core counts, each processor core of an IC will have to be operated at its optimal voltage and frequency while minimizing losses. This requires optimal design at the power delivery network (PDN) to keep the supply voltage as close to the regulated one as possible. To prevent interconnection losses, the goal is to bring the voltage regulation near the load. However, this requires highly miniaturized and embeddable components.

Recent technologies that show promise include, for example, the applicant’s own U.S. Patent No. 12,183,692 (“the ’692 patent”), issued Dec. 31, 2024 and entitled “Embedded Inductors and Integrated Voltage Regulators for Packaged Semiconductor Devices,” and the applicant’s recently filed U.S. Patent Application No. 18/746,605, filed Jun. 18, 2024 and entitled “Embeddable Coupled Inductors for Packaged Semiconductor Devices,” the entire contents of each of which is incorporated by reference herein. However, there remains a need for efficient design, layout, and structure of embedded power converters, especially implementations that enable the last stage voltage down conversion (Vₒ < Vᵢ) at the substrate core (close to the point of load) to minimize joule heating (I²R losses) and enable multidomain and multiphase operation in order to efficiently deliver high currents.

### BRIEF SUMMARY

The present disclosure contemplates various devices and methods for overcoming the above drawbacks accompanying the related art. One aspect of the embodiments of the present disclosure is a method of manufacturing a semiconductor device. The method may comprise embedding a first inductor and a first capacitor in a substrate core of a substrate. The first inductor and the first capacitor may define a first LC module. The method may further comprise providing an input terminal of the first LC module on a first side of the substrate core connected to an input of the first inductor. The input terminal of the first LC module may be configured to receive an input voltage Vᵢ and an input current Iᵢ that vary with time. The method may further comprise providing an output terminal of the first LC module on a second side of the substrate core connected to an output of the first inductor and to an anode of the first capacitor. The output terminal of the first LC module may be configured to output an output voltage Vₒ < Vᵢ and an output current Iₒ that vary with time. The method may further comprise providing a sense terminal on the first side of the substrate core connected to the output of the first inductor and to the anode of the first capacitor. The sense terminal may provide a feedback loop for regulating an output of a prior stage active component (e.g., control system) that becomes an input to the first LC module. The method may further comprise mounting an integrated circuit (IC) die on the substrate such that the first LC module is in alignment with a first power rail of the IC die.

Another aspect of the embodiments of the present disclosure is a method of manufacturing a semiconductor device. The method may comprise embedding a first inductor and a first capacitor in a substrate core of a substrate. The first inductor and the first capacitor may define a first LC module. The method may further comprise embedding a second inductor and a second capacitor in the substrate core. The second inductor and the second capacitor may define a second LC module that is electrically isolated from the first LC module. The method may further comprise providing an input terminal of the first LC module on a first side of the substrate core connected to an input of the first inductor. The input terminal of the first LC module may be configured to receive an input voltage Vᵢ₁ and an input current Iᵢ₁ that vary with time. The method may further comprise providing an input terminal of the second LC module on the first side of the substrate core connected to an input of the second inductor. The input terminal of the second LC module may be configured to receive an input voltage Vᵢ₂ and an input current Iᵢ₂ that vary with time (Iᵢ₂ may be out of phase with Iᵢ₁). The method may further comprise providing an output terminal of the first LC module on a second side of the substrate core connected to an output of the first inductor and to an anode of the first capacitor. The output terminal of the first LC module may be configured to output an output voltage Vₒ₁ < Vᵢ₁ and an output current Iₒ₁ that vary with time. The method may further comprise providing an output terminal of the second LC module on the second side of the substrate core connected to an output of the second inductor and to an anode of the second capacitor. The output terminal of the second LC module may be configured to output an output voltage Vₒ₂ < Vᵢ₂ and an output current Iₒ₂ that vary with time. The method may further comprise providing a first sense terminal on the first side of the substrate core connected to the output of the first inductor and to the anode of the first capacitor. The first sense terminal may provide a feedback loop for regulating an output of a prior stage active component (e.g., control system) that becomes an input to the first LC module. The method may further comprise providing a second sense terminal on the first side of the substrate core connected to the output of the second inductor and to the anode of the second capacitor. The second sense terminal may provide a feedback loop for regulating an output of a prior stage active component (e.g., control system) that becomes an input to the second LC module. The method may further comprise mounting an integrated circuit (IC) die on the substrate such that the first LC module is in alignment with a first power rail of the IC die and the second LC module is in alignment with a second power rail of the IC die.

Another aspect of the embodiments of the present disclosure is a method of manufacturing a semiconductor device. The method may comprise providing a first LC module including a first inductor and a first capacitor and embedding the first LC module in a substrate core of a substrate such as a package substrate, interposer, or printed circuit board (PCB). Providing the first LC module may include encapsulating the first inductor and the first capacitor with a polymer to produce an embeddable tile containing the first LC module. The method may further comprise providing an input terminal of the first LC module on a first side of the substrate core connected to an input of the first inductor. The input terminal of the first LC module may be configured to receive an input voltage Vᵢ and an input current Iᵢ that vary with time. The method may further comprise providing an output terminal of the first LC module on a second side of the substrate core connected to an output of the first inductor and to an anode of the first capacitor. The output terminal of the first LC module may be configured to output an output voltage Vₒ < Vᵢ and an output current Iₒ that vary with time. The method may further comprise providing a sense terminal on the first side of the substrate core connected to the output of the first inductor and to the anode of the first capacitor. The sense terminal may provide a feedback loop for regulating an output of a prior stage active component that becomes an input to the first LC module. The method may further comprise mounting an integrated circuit (IC) die on the substrate such that the first LC module is in alignment with a first power rail of the IC die.

In any of the above aspects, the prior stage active component may be external to the substrate core. Embedding the first inductor may comprise embedding a first magnetic core in the substrate core and forming a conductive via extending through the first magnetic core. Embedding the first capacitor may comprise embedding a first stack of one or more capacitive elements in the substrate core. Each of the one or more capacitive elements may comprise a conductive substrate having a front side and a back side, a dielectric layer on the front side of the conductive substrate, and a conductive polymer layer on the dielectric layer, the conductive polymer layer of each capacitive element being electrically insulated from the conductive substrate of each capacitive element of the first stack. The output terminal of the first LC module may be connected to the conductive substrate of each capacitive element of the first stack. The first stack of one or more capacitive elements may include a first capacitive element and a second capacitive element. The back sides of the first and second capacitive elements may face each other with a laminate therebetween. The first inductor may include a plurality of inputs for carrying current at different interleaved phases. Providing the input terminal of the first LC module may comprise providing a plurality of input terminals on the first side of the substrate core connected respectively to the plurality of inputs of the first inductor. The method may comprise forming a conductive via though the substrate core and electrically connected to the conductive substrate of each capacitive element of the first stack (corresponding to the anode). The output terminal of the first LC module may be connected to the output of the first inductor and to the anode of the first capacitor via a redistribution layer (RDL). A further conductive via may be formed through the substrate core and electrically connected to the conductive polymer layers of each capacitive element of the first stack (corresponding to the cathode).

In any of the above aspects, the method may comprise embedding a second inductor in the substrate core. The first LC module may include the second inductor, the output terminal of the first LC module may further be connected to the output of the second inductor, and the sense terminal may further be connected to the output of the second inductor. The method may comprise providing a second input terminal of the first LC module on the first side of the substrate core connected to an input of the second inductor. The method may comprise embedding a second capacitor in the substrate core. The first LC module may include the second capacitor, the output terminal of the first LC module may further be connected to an anode of the second capacitor, and the sense terminal may further be connected to the anode of the second capacitor.

Another aspect of the embodiments of the present disclosure is a package substrate of a semiconductor device. The package substrate may comprise a substrate core and a first LC module embedded in the substrate core and including a first inductor and a first capacitor. The package substrate may further comprise an input terminal of the first LC module on a first side of the substrate core connected to an input of the first inductor. The input terminal of the first LC module may be configured to receive an input voltage Vᵢ and an input current Iᵢ that vary with time. The package substrate may further comprise an output terminal of the first LC module on a second side of the substrate core connected to an output of the first inductor and to an anode of the first capacitor. The output terminal of the first LC module may be configured to output an output voltage Vₒ < Vᵢ and an output current Iₒ that vary with time. The package substrate may further comprise a sense terminal on the first side of the substrate core connected to the output of the first inductor and to the anode of the first capacitor. The sense terminal may provide a feedback loop for regulating an output of a prior stage active component.

Another aspect of the embodiments of the present disclosure is a tile embeddable in a substrate of a semiconductor device. The tile may comprise a first LC module surrounded by a polymer encapsulation and including a first inductor and a first capacitor. The tile may further comprise an input terminal of the first LC module on a first side of the polymer encapsulation connected to an input of the first inductor. The input terminal of the first LC module may be configured to receive an input voltage Vᵢ and an input current Iᵢ that vary with time. The tile may further comprise an output terminal of the first LC module on a second side of the polymer encapsulation connected to an output of the first inductor and to an anode of the first capacitor. The output terminal of the first LC module may be configured to output an output voltage Vₒ < Vᵢ and an output current Iₒ that vary with time. The tile may further comprise a sense terminal on the first side of the polymer encapsulation connected to the output of the first inductor and to the anode of the first capacitor. The sense terminal may provide a feedback loop for regulating an output of a prior stage active component.

Another aspect of the embodiments of the present disclosure is a semiconductor device. The semiconductor device may comprise a substrate (e.g., a package substrate, interposer, or printed circuit board (PCB)), an integrated circuit die on the substrate, and a first LC module embedded in the substrate in alignment with a first power rail of the integrated circuit die. The first LC module may include a first inductor and a first capacitor. The semiconductor device may further comprise an input terminal of the first LC module on a first side of the substrate connected to an input of the first inductor. The input terminal of the first LC module may be configured to receive an input voltage Vᵢ and an input current Iᵢ that vary with time. The semiconductor device may further comprise an output terminal of the first LC module on a second side of the substrate connected to an output of the first inductor and to an anode of the first capacitor. The output terminal of the first LC module may be configured to output an output voltage Vₒ < Vᵢ and an output current Iₒ that vary with time. The semiconductor device may further comprise a sense terminal on the first side of the substrate connected to the output of the first inductor and to the anode of the first capacitor. The sense terminal may provide a feedback loop for regulating an output of a prior stage active component.

In any of the above aspects, the prior stage active component may be external to the substrate core, the substrate, or the polymer encapsulation. The first inductor may comprise a first magnetic core embedded in the substrate core, substrate, or polymer encapsulation and a conductive via extending through the first magnetic core. The first capacitor may comprise a first stack of one or more capacitive elements embedded in the substrate core, substrate, or polymer encapsulation. Each of the one or more capacitive elements may comprise a conductive substrate having a front side and a back side, a dielectric layer on the front side of the conductive substrate, and a conductive polymer layer on the dielectric layer, the conductive polymer layer of each capacitive element being electrically insulated from the conductive substrate of each capacitive element of the first stack. The output terminal of the first LC module may be connected to the conductive substrate of each capacitive element of the first stack. The first stack of one or more capacitive elements may include a first capacitive element and a second capacitive element. The back sides of the first and second capacitive elements may face each other with a laminate therebetween. The first inductor may include a plurality of inputs for carrying current at different interleaved phases. The package substrate, tile, or semiconductor device may comprise a plurality of input terminals on the first side of the substrate core, substrate, or polymer encapsulation connected respectively to the plurality of inputs of the first inductor. The package substrate, tile, or semiconductor device may comprise a conductive via formed through the substrate core, substrate, or polymer encapsulation and electrically connected to the conductive substrate of each capacitive element of the first stack (corresponding to the anode). The package substrate, tile, or semiconductor device may comprise a redistribution layer (RDL) in which the output terminal of the first LC module is connected to the output of the first inductor and to the anode of the first. A further conductive via may be formed through the substrate core and electrically connected to the conductive polymer layers of each capacitive element of the first stack (corresponding to the cathode). The first LC module may include a second inductor, the output terminal of the first LC module may be connected to the output of the second inductor, and the sense terminal may be connected to the output of the second inductor. The package substrate, tile, or semiconductor device may comprise a second input terminal of the first LC module on the first side of the substrate core, substrate, or polymer encapsulation connected to an input of the second inductor. The first LC module may include a second capacitor, the output terminal of the first LC module may be connected to an anode of the second capacitor, and the sense terminal may be connected to the anode of the second capacitor.

The package substrate, tile, or semiconductor device may comprise a second LC module embedded in the substrate core, substrate, or polymer encapsulation and including a first inductor and a first capacitor. The second LC module may be electrically isolated from the first LC module. The package substrate, tile, or semiconductor device may comprise a second input terminal on the first side of the substrate core, substrate, or polymer encapsulation connected to an input of the first inductor of the second LC module. The package substrate, tile, or semiconductor device may comprise a second output terminal on the second side of the substrate core, substrate, or polymer encapsulation connected to an output of the first inductor of the second LC module and to an anode of the first capacitor of the second LC module. The package substrate, tile, or semiconductor device may comprise a second sense terminal on the first side of the substrate core, substrate, or polymer encapsulation connected to the output of the first inductor of the second LC module and to the anode of the first capacitor of the second LC module. The second sense terminal may provide a feedback loop for regulating an output of a prior stage active component.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic representation of a power converter;

FIG. 2 is a schematic representation of an LC circuit of the power converter;

FIG. 3 is a top view of an integrated passive device (IPD) embodying the LC circuit of the power converter in an LC module thereof;

FIG. 4 is a cross-sectional view of the IPD taken along the line 4-4 in FIG. 3;

FIG. 4A is a close-up view of the portion labeled 4A in FIG. 4;

FIG. 5 is a schematic representation of an array of LC circuits of power converters supporting multiphase multidomain (voltage) input to a load, which may be embodied in LC modules placed under the shadow of the load;

FIG. 6 is a perspective view of a substrate including the IPD (LC modules) and layout representation of the LC circuits of FIG. 5;

FIG. 7 is a cross-sectional view of a semiconductor device including the substrate with the IPD (LC modules);

FIG. 8 is a top view of the IPD showing another example LC module embodying the LC circuit of the power converter;

FIG. 9 is a cross-sectional view of the IPD taken along the line 9-9 in FIG. 8;

FIG. 10 is a top view of the IPD showing another example LC module embodying the LC circuit of the power converter;

FIG. 11 is a cross-sectional view of the IPD taken along the line 11-11 in FIG. 10;

FIG. 12 is a cross-sectional view of the IPD showing another example LC module embodying the LC circuit of the power converter; and

FIG. 13 is a cross-sectional view of a capacitor of the IPD.

### DETAILED DESCRIPTION

The present disclosure encompasses various embodiments of methods of manufacturing LC circuits including inductors and capacitors to be embedded in a package substrate, interposer, or printed circuit board (PCB) of a semiconductor device or to be surface mounted, along with the resulting devices and intermediate products thereof. The detailed description set forth below in connection with the appended drawings is intended as a description of several currently contemplated embodiments and is not intended to represent the only form in which the disclosed subject matter may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

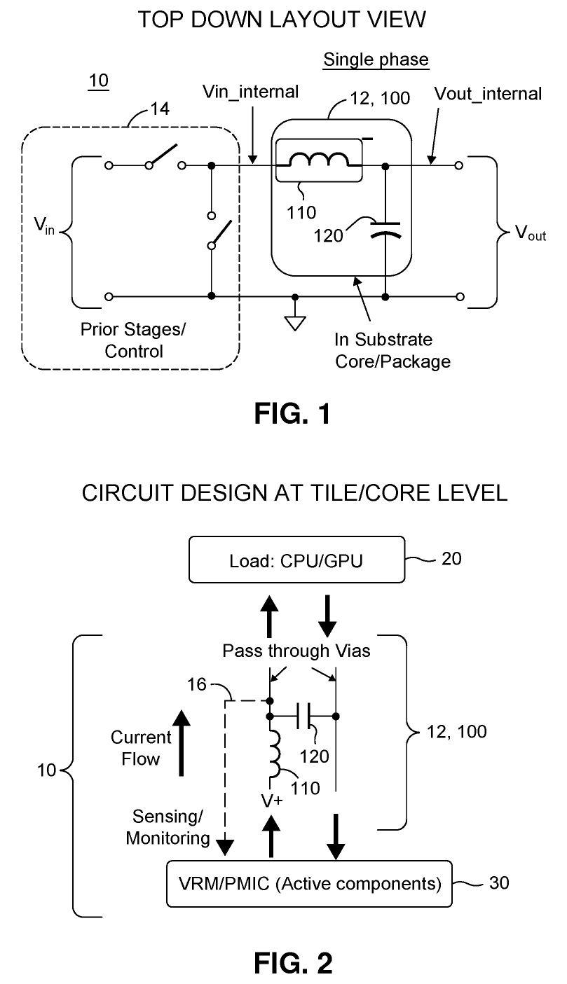

FIG. 1 is a schematic representation of a power converter 10 showing an implementation layout thereof. The power converter 10, which may be a buck converter, for example, may be divided as shown, with an LC circuit 12 thereof and/or other passive components being implemented as an integrated passive device (IPD) 100, while prior stage(s) 14 are separated out and implemented external to the IPD 100. These prior stage(s) 14 may include power modules such as power management integrated circuits (PMICs), voltage regulator modules (VRMs), and other active components of the power converter 10 or control systems thereof. Owing to the separation out of the active components, the remaining LC circuit 12 and/or other passive components of the power converter 10 may be advantageously placed (as an IPD 100) within a package substrate, interposer, or printed circuit board (PCB) in close proximity to the load, namely, a CPU, GPU, or other IC, thereby reducing parasitics and beneficially improving efficiency of the power converter 10.

FIG. 2 is another schematic representation of the power converter 10, namely, a side view thereof, together with the CPU, GPU, or other IC 20 that constitutes the load. The side view of FIG. 2 emphasizes a preferred implementation in which the IPD 100 embodying the LC circuit 12 is positioned directly underneath the load (i.e., in the shadow of the die). In particular, an LC module of the IPD 100 (containing an LC circuit 12 for servicing a given power domain) may be aligned with a corresponding power rail of the CPU, GPU, or other IC 20 that constitutes the load. On the opposite side, i.e., beneath the IPD 100, the prior stage(s) 14 of the power converter 10 may be embodied in VRM(s), PMIC(s), and/or other active components 30, which may provide inputs to the IPD 100 as well as receive sensing/monitoring feedback from the IPD 100. Passthrough vias may also be provided for signal transmission between the IC 20 and the active components 30 of the power converter 10 (or other external devices) through the IPD 100. The IPD 100 may thus realize a vertical power delivery circuit that is efficiently embedded in a package substrate, interposer, or PCB on which the IC 20 may be mounted.

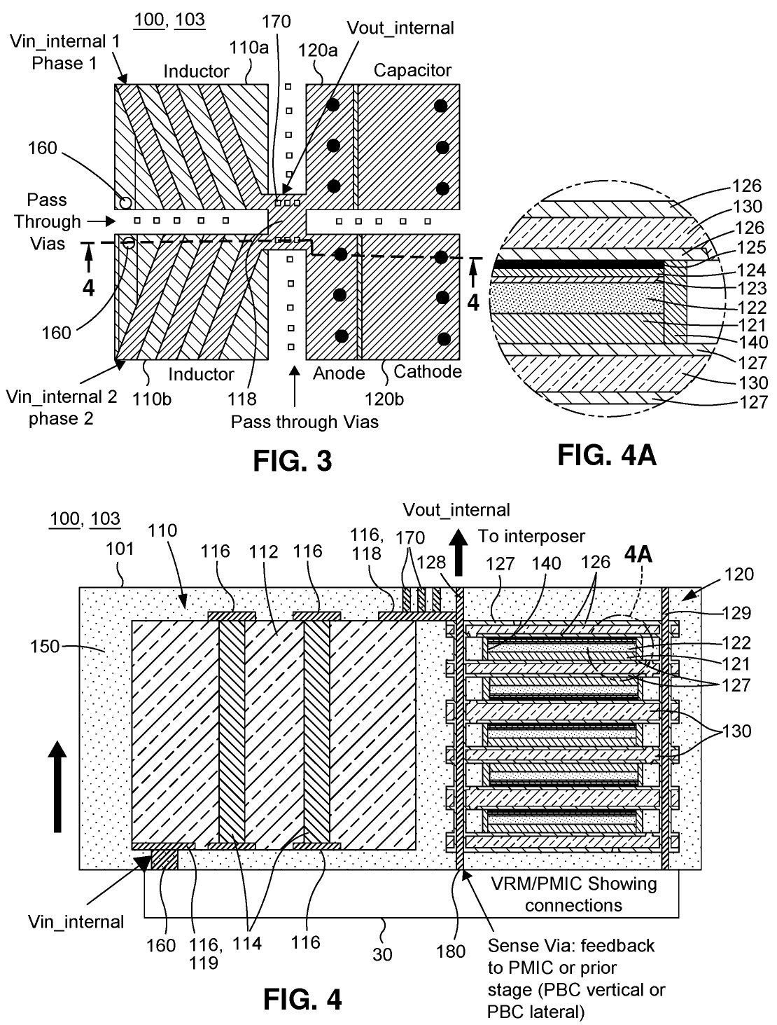

Referring to FIGS. 3 and 4, an example IPD 100 is illustrated, showing one possible realization of an LC circuit 12 of the power converter 10. The IPD 100 may include one or more LC modules 103 (FIGS. 3 and 4 showing a single LC module 103) that are embedded in a substrate core 101 of a substrate such as a package substrate, interposer, or PCB. The first LC module 103 may be defined by one or more inductors 110a, 110b (generically inductor(s) 110) and one or more capacitors 120a, 120b (generically inductor(s) 120). As shown in FIG. 4, each inductor 110 may comprise a magnetic core 112 that is embedded in the substrate core 101 and one or more conductive vias 114 extending through the magnetic core 112. Each inductor 110 may additionally comprise one or more conductive lateral segments 116 (realized as metal patterning, for example) in order to extend the conductive path defined by the conductive vias 114 into one or more windings (and/or fractions of a winding) that wrap around the magnetic core 112, thus increasing inductance. On one end of the conductive path, the last lateral segment 116 (e.g., on the top as shown) may serve as an output 118 of the inductor 110, and on the other end of the conductive path, the last lateral segment 116 (e.g., on the bottom as shown) may serve as an input 119 of the inductor 110. Current may thus flow through from the input 119 to the output 118 of the inductor 110 (from the bottom to the top in FIG. 4) through the conductive path defined by the vias 114 and lateral segments 116.

Referring additionally to the closeup view of FIG. 4A, each capacitor 120 may include a stack of one or more capacitive elements embedded in the substrate core 101 (e.g., five capacitive elements shown in the example of FIG. 4). Each capacitive element may comprise a conductive substrate 121 having a front side and a back side, a dielectric layer 123 on the front side of the conductive substrate 121 (e.g., on a high surface area portion 122 thereof), and a conductive polymer layer 124 on the dielectric layer 123. The conductive polymer layer(s) 124 of all capacitive element(s) in the stack may collectively serve as the cathode of the capacitor 120. These conductive polymer layer(s) 124 (collectively serving as the cathode) may be electrically insulated from the conductive substrate(s) 121 of all capacitive elements in the stack, which may collectively serve as the anode of the capacitor 120. In this regard, the conductive polymer layer 124 of each capacitive element may be connected to one or more cathode terminal metallization layers 126 (e.g., via a carbonaceous layer 125 for improved electrical connection), while the conductive substrate 121 of each capacitive element may be connected to one or more anode terminal metallization layers 127 (e.g., by direct contact with the back side of the conductive substrate 121 not having the high surface area portion 122). The cathode terminal metallization layers 126 may be electrically connected together (e.g., by a conductive via 129) to define a cathode terminal of the capacitor 120, and likewise the anode terminal metallization layers 127 may be electrically connected together (e.g., by a conductive via 128) to define an anode terminal of the capacitor 120. Electrical isolation between the anode and cathode (as well as mechanical strength to prevent delamination and disintegration of the structure) may be ensured by providing insulating material 130, 140 (e.g., laminate) between and around the stacked capacitive elements.

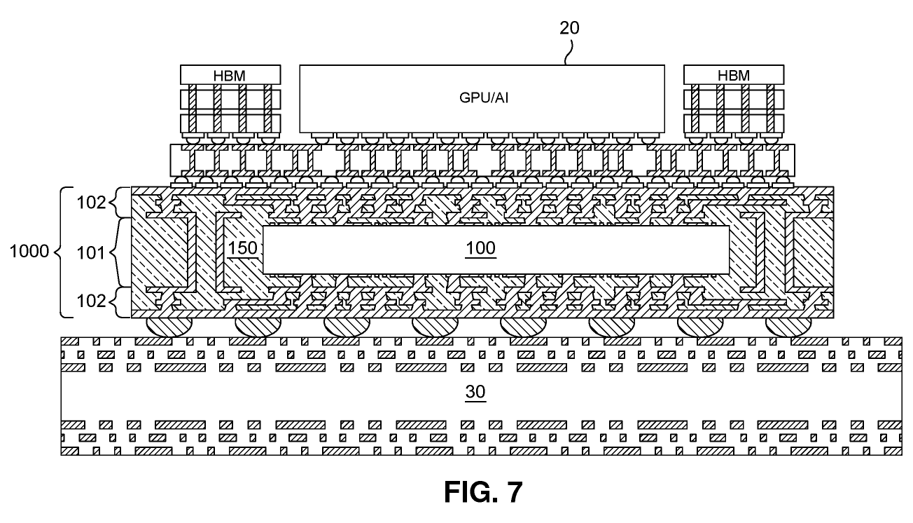

Continuing to refer to FIGS. 3 and 4, and with additional reference to FIG. 7, the IPD 100 (or each individual LC module 103 thereof in a case where there are more than one) may be embedded within an insulating material 150 (e.g., laminate) of the substrate core 101. In general, the substrate 1000 (which may be a package substrate as shown in FIG. 7 but may also be an interposer or PCB, for example) may comprise the substrate core 101 in addition to one or multiple redistribution layers (RDL) 102 on either side of the substrate core 101. The LC module 103 may have an input terminal 160 on a first side of the substrate core 101 in which the IPD 100 is embedded (the bottom in FIG. 4), with the input terminal 160 being electrically connected to the input 119 of the inductor 110. The input terminal 160 may comprise one or more conductive vias that extend through the insulating material 150 of the substrate core 101 to the input 119 of the inductor 110, for example, in combination with a conductive pad and/or metal patterning outside the substrate core 101 (e.g., in an RDL 102 or on a surface of the substrate 1000). The input terminal 160 may be configured to receive (e.g., from component(s) 30 embodying the prior stage(s) 14 of the power converter 10) an input voltage Vᵢ and an input current Iᵢ that vary with time. It is noted that such prior stage active component(s) 30 may be external to the substrate core 101 and may be external to the substrate 1000 entirely, facilitating the placement of only the passive components of the power converter 10 near the IC 20.

The LC module 103 may likewise have an output terminal 170 on a second side of the substrate core 101 (the top in FIG. 4), with the output terminal 170 being electrically connected to the output 118 of the inductor 110 and to the anode of the capacitor 120, namely, the conductive via 128 and/or anode terminal metallization layer(s) 127 thereof. In this way, the output terminal 170 may be electrically connected to the conductive substrate 121 of each capacitive element making up the capacitor 120. Like the input terminal 160, the output terminal 170 of the LC module 103 may comprise one or more conductive vias that extend through the insulating material 150 of the substrate core 101, in this case to the output 118 of the inductor 110 for example (which may be electrically connected to the anode of the capacitor 120), in combination with a conductive pad and/or metal patterning outside the substrate core 101 (e.g., in an RDL 102 or on a surface of the substrate 1000). In an implementation where a conductive via 128 is formed connecting the anode terminal metallization layers 127 of the capacitor 120 together as described above, the conductive via 128 may likewise serve as the output terminal 170 of the capacitor 120. The output terminal 170 may be configured to output (e.g., to the IC 20) an output voltage Vₒ < Vᵢ and an output current Iₒ that vary with time. The cathode terminal (e.g., cathode terminal metallization layer(s) 126 and conductive via 129) may be electrically connected to ground in the same way (e.g., through the RDL 102, etc.).

Referring back to FIG. 2, the preferred implementation of the power converter 10 (in which the LC circuit 12 is positioned directly underneath the load 20) may further provide for sensing or monitoring the output of the power converter 10. To this end, a feedback loop 16 is depicted in FIG. 2, which may provide an electrical connection to the output of the inductor 110 (and to the anode of the capacitor 120) from underneath the LC circuit 12, allowing for convenient feedback to the VRM(s), PMIC(s), and/or other active components 30. As shown in FIG. 4, the feedback loop 16 may be embodied in the same conductive via 128 that connects the anode terminal metallization layers 127 of the capacitor 120 together (and that is in electrical contact with the output 118 of the inductor 110). As such, the LC module 103 may have a sense terminal 180 on the first side of the substrate core 101 (the bottom in FIG. 4), with the sense terminal 180 being electrically connected to the output 118 of the inductor 110 and to the anode of the capacitor 120, namely, the conductive via 128 and/or anode terminal metallization layer(s) 127 thereof. The sense terminal 180 of the LC module 103 may comprise an end portion of the conductive via 128 (on the bottom in FIG. 4), which may extend through the insulation material 150 of the substrate core 101, in combination with a conductive pad and/or metal patterning outside the substrate core 101 (e.g., in an RDL 102 or on a surface of the substrate 1000). The sense terminal 180 may thus provide a feedback loop 16 (see FIG. 2) for regulating an output(s) of one or more prior stage active component(s) 30 (e.g., control system(s)) that becomes an input to the LC module 103. In this way, the disclosed subject matter may allow for closed feedback control to a power regulator such as a PMIC or VRM. The power regulator may house the active components (e.g., FETs) and other passives to enable power conversion, with the final stage of conversion being done within the IPD 100.

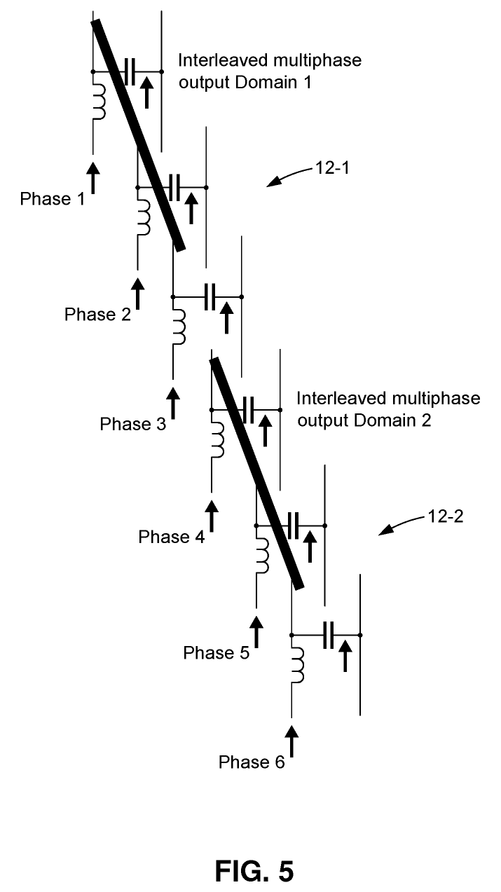

FIG. 5 is a schematic representation of an array of LC circuits 12 (12-1, 12-2, etc.) supporting multiphase multidomain input by the power converter 10 to the load 20. The array of LC circuits 12 may be embodied in the same IPD 100 described above in relation to FIGS. 3, 4, and 4A. For example, as noted above and shown in FIG. 3, a single LC module 103 may include more than one inductor 110a, 110b and/or more than one capacitor 120a, 120b. The arrangement of the two inductors 110a, 110b and the two capacitors 120a, 120b as shown in FIG. 3, symmetrically structured and sharing a central output terminal 170, is one possible implementation of an LC circuit 12-1 having two-phase interleaved inputs (e.g., Phase 1 and Phase 2 in FIG. 5). The same LC module structure of FIG. 3 may be used for additional phases as well (e.g., Phase 3 in FIG. 5, etc.) simply by duplicating the structure to define an additional one or more inductors (e.g., 110c, etc.) and an additional one or more capacitors (e.g., 120c, etc.) and connecting together the output terminals 170 of the two LC modules 103 (e.g., in an RDL 102, see FIG. 7). Alternatively, the LC module structure of FIG. 3 may itself be modified to accommodate a third or additional pairs of inductor 110 and capacitor 120 that all share the same output terminal 170 within the substrate core 101. To accommodate a second power domain, a second LC circuit 12-2 may similarly be implemented as one or more interconnected LC modules 103 (e.g., having the layout shown in FIG. 3 or a modified layout), with the LC module(s) 103 of the second LC circuit 12-2 being electrically isolated from the LC module(s) 103 of the first LC circuit 12-1. The second LC circuit 12-2 may similarly support multiphase inputs (e.g., Phase 4, Phase 5, and Phase 6 in FIG. 5) in the same way as described in relation to the first LC circuit 12-1.

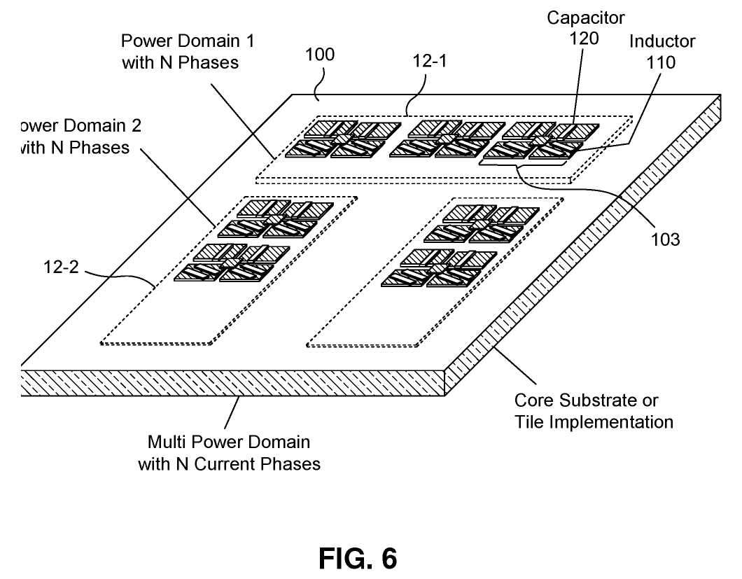

In FIG. 6, an example IPD 100 is illustrated, showing one possible realization of an array of LC circuits 12 (12-1, 12-2, etc.) of the power converter 10. A plurality of LC modules 103 may be laid out within the same IPD 100 (to be embedded in the core 101 of a substrate 1000 as shown in FIG. 7). As shown by way of example, a first power domain of the load (Power Domain 1) may be serviced by a first LC circuit 12-1, which may contain one or more LC modules 103 including inductor(s) 110 and capacitor(s) 120 like those shown in FIGS. 3, 4, and 4A. In the illustrated example of FIG. 6, three identical LC modules 103 are shown, each containing two inductors 110, for a total of six phases in Power Domain 1. The three LC modules 103, insofar as they are servicing the same power domain, may be interconnected within the RDL 102, for example (see FIG. 7). A second power domain of the load (Power Domain 2) may be serviced by a second LC circuit 12-2, which may likewise contain one or more LC modules 103 including inductor(s) 110 and capacitor(s) 120 (which are isolated from those of the first power domain by dielectric material of the substrate core 101, for example). In the illustrated example, two identical LC modules 103 are shown, for a total of four phases in Power Domain 2 (with the two LC modules 103 being interconnected within the RDL 102). Additional power domains may similarly be serviced by additional LC circuits 12 embodied in additional LC modules 103. Within the entire IPD 100, the various LC circuits 12 may be positioned so as to be directly aligned with (e.g., underneath) the corresponding power rails of the load. That is, the LC module(s) 103 embodying the first LC circuit 12-1 may be positioned within the plane of the IPD 100 (in x- and y-directions) so as to be aligned with (and thus as close as possible to) the power rails of Power Domain 1. In the same way, the LC module(s) 103 embodying the second LC circuit 12-2 may be positioned within the plane of the IPD 100 (in x- and y-directions) so as to be aligned with (and thus as close as possible to) the power rails of Power Domain 2, and so on. Thus, when the IC 20 is mounted on the substrate 1000 containing the embedded IPD 100, parasitics will be minimized and the efficiency of the power converter 10 will be enhanced. One or more such IPDs 100 can be tailored to the particular IC 20 and semiconductor package environment, enabling efficient multiphase and multidomain power delivery to the load. Passthrough vias for signal transmission through the IPDs 100 may also be provided, located as desired for the particular implementation (see, e.g., FIG. 3).

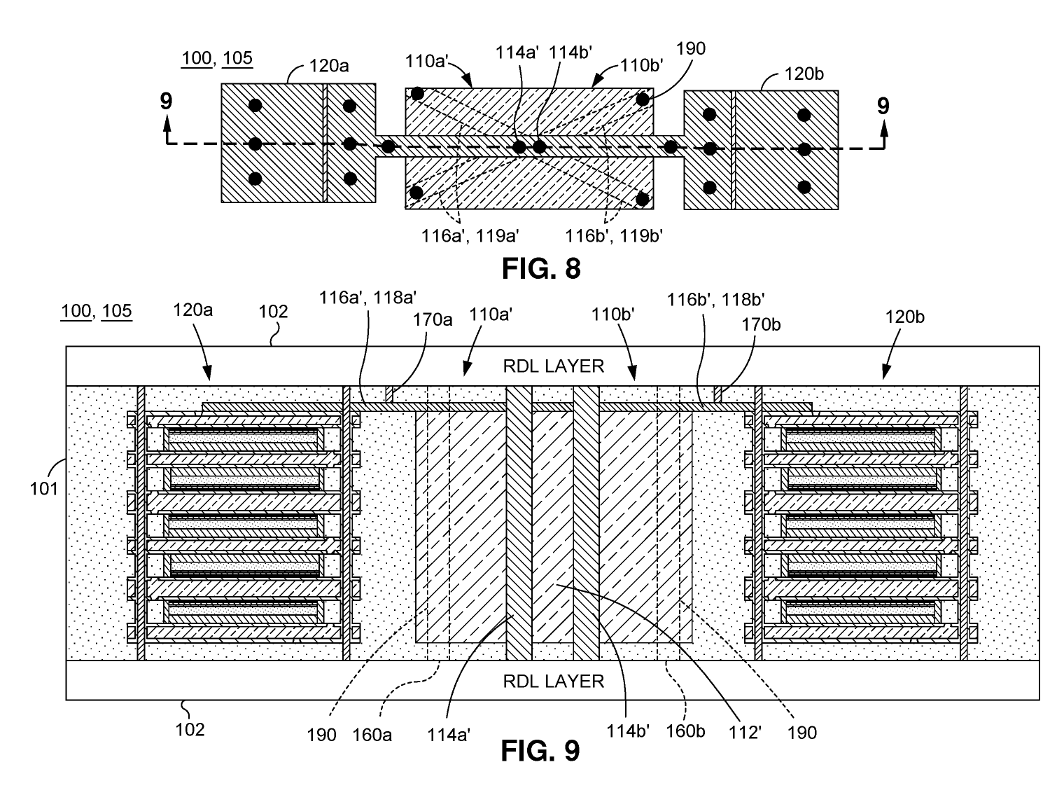

Referring to FIGS. 8 and 9, another example IPD 100 is illustrated, this time showing an alternate realization of an LC circuit 12 of the power converter 10 in the form of an LC module 105. As noted above in relation to FIGS. 3-6, the IPD 100 may include one or more LC modules 103 that are embedded in a substrate core 101 of a substrate 1000. The IPD 100 may instead or additionally include LC modules 105, which differ from LC modules 103 in the specific design of the inductor(s) 110a’, 110b’ (generically inductors 110’), which are modified in relation to the inductor(s) 110 as well as in their arrangement relative to the capacitor(s) 120. As shown in FIGS. 8 and 9, each inductor 110’ may comprise a magnetic core 112’ that is embedded in the substrate core 101 and one or more conductive vias 114a’, 114b’ (generically vias 114’) extending through the magnetic core 112’. Each inductor 110’ may additionally comprise one or more conductive lateral segments 116a’, 116b’ (generically lateral segments 116’), which may be realized as metal patterning, for example, in order to extend the conductive path defined by the conductive vias 114’ into one or more windings (and/or fractions of a winding) that wrap around the magnetic core 112’, thus increasing inductance. On one end of the conductive path (e.g., on the top as shown in FIGS. 8 and 9), a respective lateral segment 116a’, 116b’ may serve as an output 118a’, 118b’ (generically output 118’) of each inductor 110’, though it is noted that these two lateral segments 116’ may (or may not) be formed from one continuous piece of metal as shown. On the other end of the conductive path (e.g., on the bottom as shown in phantom in FIG. 8), there may be one or more lateral segments 116a’ serving as an input 119a’ of one inductor 110a’ and one or more lateral segments 116b’ serving as an input 119b’ of the other inductor 110b’. As illustrated, these bottom lateral segments 116’ may extend outward toward the corners of the magnetic core 112’ in order to maximize the length of the conductive path, while also splitting into multiple paths to provide for inputs of different phases, for example.

Thus, as shown in FIGS. 8 and 9, the pair of inductors 110’ may include a first inductor 110a’ (on the left-hand side in FIG. 8) defining a conductive path that extends from a bottom lateral segment 116a’ serving as the input 119a’ of the first inductor 110a’ (or a pair of bottom lateral segments 116a’ serving as different phase inputs 119a’), up through a conductive via 114a’, and along a further lateral segment 116a’ on the top serving as the output 118a’ of the first inductor 110a’. Symmetrically formed thereto in relation to the same magnetic core 112’, the pair of inductors 110’ may further include a second inductor 110b’ (on the right-hand side in FIG. 8) defining a conductive path that extends from a bottom lateral segment 116b’ serving as the input 119b’ of the second inductor 110b’ (or a pair of bottom lateral segments 116b’ serving as different phase inputs 119b’), up through a conductive via 114b’, and along a further lateral segment 116b’ on the top serving as the output 118b’ of the second inductor 110b’.

Like the input terminal 160 of the LC module 103 described above, the LC module 105 may have input terminals 160a, 160b on a first side of the substrate core 101 (the bottom in FIG. 9) electrically connected to the respective inputs 119a’, 119b’ of the first and second inductors 110a’, 110b’. Each input terminal 160a, 160b may comprise an end portion of a respective conductive via 190 (which may be used as a passthrough via, for example), in combination with a conductive pad and/or metal patterning outside the substrate core 101 (e.g., in an RDL 102 or on a surface of the substrate 1000). Like the output terminal 170 of the LC module 103, the LC module 105 may have output terminals 170a, 170b (generically, output terminals 170) on a second side of the substrate core 101 (the top in FIG. 9), with the output terminals 170a, 170b being electrically connected to the outputs 118a’, 118b’ of the respective inductors 110a’, 110b’ and to the anodes of the respective capacitors 120a, 120b (the capacitors 120 being the same as described above in relation to FIG. 3 and 4). The output terminals 170a, 170b may comprise one or more conductive vias that extend through the insulating material 150 of the substrate core 101 to the respective outputs 118a’, 118b’ of the inductors 110a’, 110b’, for example, in combination with a conductive pad and/or metal patterning outside the substrate core 101 (e.g., in an RDL 102 or on a surface of the substrate 1000).

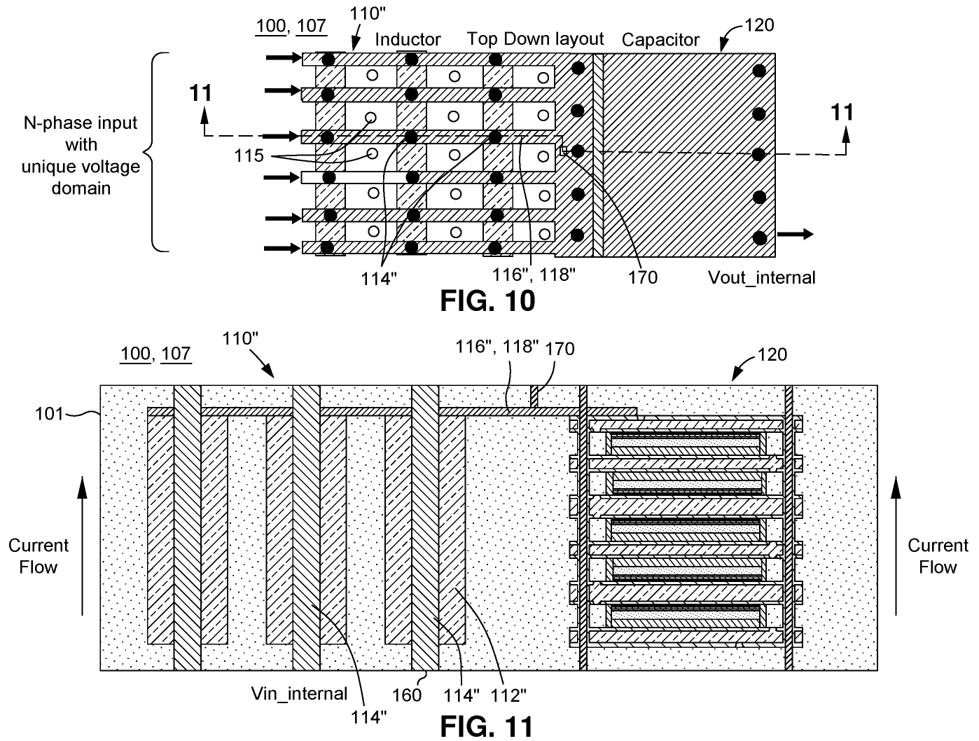

Referring to FIGS. 10 and 11, another example IPD 100 is illustrated, this time showing an alternate realization of an LC circuit 12 of the power converter 10 in the form of an LC module 107. As noted above in relation to FIGS. 3-6 and in relation to FIGS. 8 and 9, the IPD 100 may include one or more LC modules 103, 105 that are embedded in a substrate core 101 of a substrate 1000. The IPD 100 may instead or additionally include LC modules 107, which differ from LC modules 103 in the specific design of the inductor(s) 110”. As shown in FIGS. 10 and 11, the inductor 110” may comprise one or more magnetic cores 112” that are embedded in the substrate core 101 and one or more conductive vias 114” extending through respective ones of the magnetic core(s) 112”. The inductor 110” may additionally comprise one or more conductive lateral segments 116”, which may be realized as metal patterning, for example, in order to extend the conductive path defined by the conductive vias 114” into one or more windings (and/or fractions of a winding) that wrap around the magnetic core(s) 112”, thus increasing inductance. On one end of the conductive path (e.g., on the top as shown in FIGS. 10 and 11), a lateral segment 116” may serve as an output 118” of the inductor 110”. On the other end of the conductive path (e.g., on the bottom in FIG. 11), the bottom end of each conductive via 114” (or alternatively a lateral segment connected thereto) may serve as a respective input. As illustrated, there may be many conductive paths of varying lengths, which may be arranged in a grid, for example. The illustrated grid includes six rows of three conductive paths, totaling eighteen conductive paths formed by conductive vias 114” associated respectively with eighteen inputs to the inductor 110”. As shown, the vias 114” may terminate at different positions on respective lateral segments 116”, resulting in a variety of path lengths between the respective inputs and the output 118” of the inductor 110” for multiphase input.

Like the input terminal 160 of the LC module 103 described above, the LC module 107 may have input terminals 160 on a first side of the substrate core 101 (the bottom in FIG. 11) electrically connected to the respective inputs of the inductor 110”. Each input terminal 160 may comprise an end portion of a respective conductive via 114” (which may also be used as a passthrough via, for example), in combination with a conductive pad and/or metal patterning outside the substrate core 101 (e.g., in an RDL 102 or on a surface of the substrate 1000). Like the output terminal 170 of the LC module 103, the LC module 107 may have an output terminal 170 on a second side of the substrate core 101 (the top in FIG. 11), electrically connected to the output(s) 118” of the inductor 110” and to the anodes of the capacitor 120 (which may be the same as described above in relation to FIG. 3 and 4). The output terminal 170 may comprise one or more conductive vias that extend through the insulating material 150 of the substrate core 101 to the respective output(s) 118” of the inductor 110”, for example, in combination with a conductive pad and/or metal patterning outside the substrate core 101 (e.g., in an RDL 102 or on a surface of the substrate 1000). Passthrough vias 115 (see FIG. 10) for signal transmission through the IPDs 100 may also be provided, located as desired for the particular implementation.

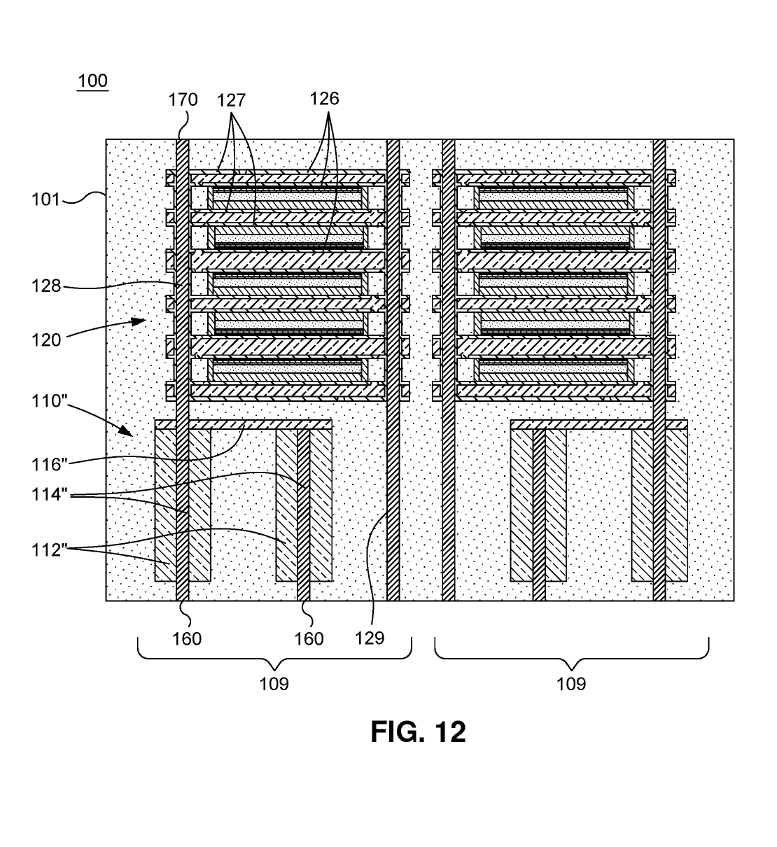

Referring to FIG. 12, another example IPD 100 is illustrated, this time showing an alternate realization of an LC circuit 12 of the power converter 10 in the form of an LC module 109 (two such LC modules 109 shown in FIG. 12). As noted above in relation to FIGS. 3-6, in relation to FIGS. 8 and 9, and in relation to FIGS. 10 and 11, the IPD 100 may include one or more LC modules 103, 105, 107 that are embedded in a substrate core 101 of a substrate 1000. The IPD 100 may instead or additionally include LC modules 109. The LC module 109 differs from the LC module 107 only in the arrangement of the inductor 110” and the capacitor 120, so the same reference numbers are used. In particular, as shown in FIG. 12, the inductor 110” may comprise one or more magnetic cores 112” that are embedded in the substrate core 101 and one or more conductive vias 114” extending through respective ones of the magnetic core(s) 112”. The inductor 110” may additionally comprise one or more conductive lateral segments 116”, which may be realized as metal patterning, for example, in order to extend the conductive path defined by the conductive vias 114” into one or more windings (and/or fractions of a winding) that wrap around the magnetic core(s) 112”, thus increasing inductance. Unlike the LC module 107, in which the inductor 110” and the capacitor 120 are laid out laterally (horizontally in FIG. 11), the LC module 109 is laid out vertically as shown. In particular, the capacitor 120 may be positioned above the inductor 110” such that one of the conductive vias 114” of the inductor 110” simultaneously serves as the conductive via 128 that connects the anode terminal metallization layers 127 of the capacitor 120 together. As in the case of the LC module 107, there may be many conductive paths of varying lengths for multiphase input, with each path being defined by its own conductive via 114” and the lateral spacing thereof relative to the conductive via 128.

Like the input terminal 160 of the LC module 107 described above, the LC module 109 may have input terminals 160 on a first side of the substrate core 101 (the bottom in FIG. 12) electrically connected to the respective inputs of the inductor 110”. Each input terminal 160 may comprise an end portion of a respective conductive via 114”, in combination with a conductive pad and/or metal patterning outside the substrate core 101 (e.g., in an RDL 102 or on a bottom surface of the substrate 1000). Like the output terminal 170 of the LC module 107, the LC module 109 may have an output terminal 170 on a second side of the substrate core 101 (the top in FIG. 12), electrically connected to the same conductive via 114” serving as the output of the inductor 110”, as well as to the anodes of the capacitor 120 (which may be the same as described above in relation to FIG. 3 and 4). The output terminal 170 may comprise an end portion of the same conductive via 114”, for example, in combination with a conductive pad and/or metal patterning outside the substrate core 101 (e.g., in an RDL 102 or on a top surface of the substrate 1000). The cathode terminal (e.g., cathode terminal metallization layer(s) 126 and conductive via 129) may be electrically connected to ground in the same way (e.g., through the RDL 102, etc.).

Briefly, the structure and methods of manufacturing the capacitor 120 will be discussed in more detail. Referring back to FIGS. 4 and 4A, the conductive substrate 121 of each capacitive element of the capacitor 120 may be made of aluminum, an aluminum alloy, or another material (e.g., tantalum) that is etched or otherwise modified to have a high surface area, such as an etched aluminum foil as described in Applicant’s own U.S. Patent Application Pub. No. 2023/0067888, entitled “Planar High-Density Aluminum Capacitors for Stacking and Embedding,” the entire contents of which his incorporated by reference herein. As such, the conductive substrate 121 may comprise a solid metal portion (represented by reference number 121) and a high surface area (HSA) portion 122 on the front side thereof, which may include the dielectric layer 123 conformal therewith. The dielectric layer 123 may be a naturally occurring oxide layer (e.g., an aluminum oxide layer) or one that has been grown by an anodization process (e.g., by placing the conductive substrate 121 including the HSA portion 122 in an electrolytic solution and passing a current through the solution), grown by thermal oxidation in a humidity chamber, or coated on the HSA portion of the conductive substrate 121 (e.g., by atomic layer deposition). As may be appreciated, the dielectric layer 123 may, in general, exhibit the same high surface area as the underlying HSA portion 122 of the conductive substrate 121 as it fills in and takes the shape of the various tunnels and recesses that may result from the etching or other modification to the material of the conductive substrate 121.

The conductive polymer layer 124 may likewise be provided conformal with the HSA portion 122 of the conductive substrate 121, so as to be electrically isolated from the conductive substrate 121 by the dielectric layer 123. In particular, the conductive polymer layer 124 may exhibit the same high surface area as the HSA portion 122 of the underlying conductive substrate 121 as it fills in and takes the shape of the various tunnels and recesses that may result from the etching or other modification to the material of the conductive substrate 121, with the dielectric layer 123 sandwiched therebetween. A variety of conductive polymers may be suitable for use as the conductive polymer layer 124 serving as the cathode of the capacitor 120 described herein. The conductive polymer layer 124 may, for example, comprise one or more of a polypyrrole, a polythiophene, a polyaniline, a polyacetylene, a polyphenylene, a poly(p-phenylene-vinylene), PEDOT:PSS (poly(3,4-ethylenedioxythiophene) polystyrene sulfonate), or P3HT (poly(3-hexylthiophene-2,5-diyl)). In some cases, TiN or Pt may be used in place of the conductive polymer.

In addition to the dielectric layer 123 and the conductive polymer layer 124 serving as the cathode, each capacitive element of the capacitor 120 may include additional layers on the conductive polymer layer 124 in order to improve the electrical connection between the conductive polymer layer 124 and an external circuit. In this regard, the carbonaceous layer 125 (e.g., a carbon ink) may be applied on the conductive polymer layer 124, with the cathode terminal metallization layer(s) 126 (e.g., Cu) being applied on the carbonaceous layer 125. Preferably, the application of the cathode terminal metallization layer(s) 126 may comprise depositing a diffusion barrier on the carbonaceous layer 125 and depositing metal adjacent the diffusion barrier.

The carbonaceous layer 125, if included, may advantageously reduce a contact resistance between the conductive polymer layer 124 and other components, such as a diffusion barrier layer of the cathode terminal metallization layer(s) 126. The carbonaceous layer 125 may include, for example, carbon black, graphite, a carbon-based ink, or a polymeric, and may be applied using a variety of techniques, such as screen printing, inkjet printing, sputter deposition, vacuum deposition, spin coating, doctor blading, or the like. The cathode terminal metallization layer(s) 126 may be used to provide high-quality electrical conductivity between the conductive polymer layer 124 (acting as the cathode of the capacitor 120) and the conductive via 128 or other metal terminal(s) for connecting the capacitor 120 to an external circuit, for example. The cathode terminal and anode terminal metallization layers 126, 127 may include a metal such as Ag, Au, Cu, Pt, Pd, and/or composites or alloys of the aforementioned metals, or in some cases polymers such as epoxies, silicones, or fluoroelastomers. Including a diffusion barrier layer in the cathode terminal metallization layer(s) 126 may limit infiltration of components from the cathode terminal metallization layer(s) 126 into the carbonaceous layer 125 or conductive polymer layer 124. Example materials for a diffusion barrier layer include, but are not limited to, Ti, W, Cr, Ti-W, TaN, and/or Co-W. The cathode terminal and anode terminal metallization layers 126, 127, as well as any diffusion barrier layer thereof, may be applied using any suitable techniques, such as vacuum deposition (e.g., sputter deposition) or physical vapor deposition (e.g., PVD).

The capacitor 120 may include single-sided capacitive elements as illustrated (with the HSA portion 122, dielectric layer 123, and conductive polymer layer 124 being on only one side of each conductive substrate 121). Additional information about manufacturing single-sided capacitive elements is provided in the applicant’s own U.S. Patent No. 12,136,601, issued Nov. 5, 2024 and entitled “Single-Sided Embeddable Capacitors for Packaged Semiconductor Devices,” the entire contents of which his incorporated by reference herein. In order to potentially increase capacitance and minimize equivalent series resistance (ESR), double-sided capacitive elements may also be used (with HSA portion 122, dielectric layer 123, and conductive polymer layer 124 on both sides of the same conductive substrate 121). Examples of double-sided capacitive elements are described in the applicant’s own U.S. Patent Application Pub. No. 2023/0067888, filed Feb. 5, 2021 and entitled “Planar High-Density Aluminum Capacitors for Stacking and Embedding,” and U.S. Patent Application Pub. No. 2024/0021372, filed Jul.18, 2023 and entitled “Pre-Drilled Vias to Capture Double Sided Capacitance,” the entire contents of each of which is incorporated by reference herein.

Stacking arrangements of the capacitive elements may include the arrangement shown in FIG. 4, with adjacent single-sided capacitive elements being back-to-back and front-to-front (and thus alternately facing upward and downward in FIG. 4). Other arrangements are also contemplated, such as with each capacitive element facing the same direction (e.g., with the conductive polymer layer 124 of each capacitive element being above the conductive substrates 121 thereof). Additional contemplated stacking arrangements for the capacitor 120, as well as stacking methodologies, may be found in the applicant’s own U.S. Patent Application No. 18/497,808, filed Oct. 30, 2023 and entitled “Integrated Passive Devices with Enhanced Form Factor,” the entire contents of which is incorporated by reference herein.

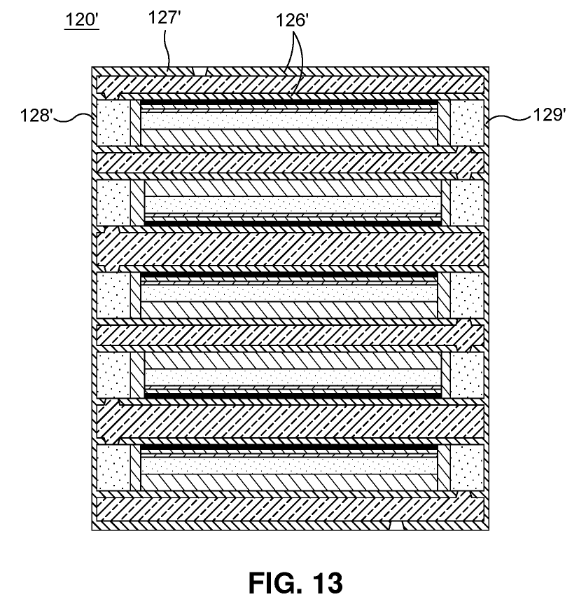

FIG. 13 is a cross-sectional view of a capacitor 120’ that may be used in place of any or all of the capacitor(s) 120 shown and described herein in relation to any of the LC modules 101, 103, 105, 107, 109 of the IPD 100. The capacitor 120’ may be the same as the capacitor 120 except that the conductive vias 128, 129 are replaced with conductive sidewalls 128’, 129’, respectively. In particular, anode terminal metallization layers 127 may be electrically connected together by the conductive sidewall 128’ to define the anode terminal of the capacitor 120’, and likewise the cathode terminal metallization layers 126 may be electrically connected together by the conductive sidewall 129’ to define the cathode terminal of the capacitor 120’. The anode terminal thus defined may be electrically connected to the output of any of the inductors 110, 110’, 110” described herein (and to an output terminal 170 of the LC circuit), while the cathode terminal may be electrically connected to ground.

The LC modules, IPDs, and semiconductor devices described herein may be manufactured either by placement of individual components within a substrate or by placement of a premade tile (containing the individual components) within the substrate. Example manufacturing methods that contemplate individual placements of inductor and capacitor components, which may be usable with the disclosed subject matter, can be found in the ’692 patent, incorporated by reference above. Example manufacturing methods that contemplate the prefabrication of a tile containing a plurality of devices (either in a packaged or unpackaged state), which may thereafter be placed in a substrate as described herein, can be found in the applicant’s own U.S. Patent Application No. 18/408,914, filed Jan. 10, 2024 and entitled “Embeddable Tiles Containing Passive Devices for Packaged Semiconductor Devices,” the entire contents of which is incorporated by reference herein. Such a tile may include a polymer encapsulation that encapsulates the passive devices, with the input and output terminals 160, 170 being formed on an outside thereof.

In general, the disclosed subject matter may provide a design, layout and structure enabling an Integrated Voltage Regulator (IVR) by bringing a multipower domain with multiphase power delivery close to the point of load. This may be done by creating an inductor and capacitor module at the package core. The implementation can be in terms of producing inductor and capacitor tiles that are embedded in the core, or alternatively by building out the core substrate with integrated inductors and capacitors. The circuit layout may be such that there is closed feedback control of the output to the power regulator. The power regulator can be in the form of PMIC or VRM, for example. The power regulator may house the active components (FETs) and other passives to enable power conversion where the final stage of conversion is done at the tile or substrate level using the inductor and capacitor module(s). The power regulator can be located close to the inductor and capacitor module(s) but may not have to be co-located. The power regulator may be located at the bottom side of the substrate and feed vertically up into the inductor and capacitor module. By bringing the inductor and capacitor close to the point of load such as a processor (e.g., CPU or GPU), the following advantages may be achieved: reduction in IR drop (which may help to limit the voltage loss in delivery to the processors), reduction in power I2R losses (which may lead to improved efficiency and reduced thermal heat generation and associated heat extraction requirements), reduced parasitic inductance loop, freeing up board space for compute use and other critical needs (e.g., I/O), and/or improves power management by enabling individual power rail control for improved temporal and spatial control.

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A method of manufacturing a semiconductor device, the method comprising:
embedding a first inductor in a substrate core of a substrate;
embedding a first capacitor in the substrate core, the first inductor and the first capacitor defining a first LC module;
providing an input terminal of the first LC module on a first side of the substrate core connected to an input of the first inductor, the input terminal of the first LC module being configured to receive an input voltage Vᵢ and an input current Iᵢ that vary with time;
providing an output terminal of the first LC module on a second side of the substrate core connected to an output of the first inductor and to an anode of the first capacitor, the output terminal of the first LC module being configured to output an output voltage Vₒ < Vᵢ and an output current Iₒ that vary with time;
providing a sense terminal on the first side of the substrate core connected to the output of the first inductor and to the anode of the first capacitor, the sense terminal providing a feedback loop for regulating an output of a prior stage active component; and
mounting an integrated circuit die on the substrate such that the first LC module is in alignment with a first power rail of the integrated circuit die.

2. The method of claim 1, wherein the prior stage active component is external to the substrate core.

3. The method of claim 1, wherein said embedding the first inductor comprises embedding a first magnetic core in the substrate core and forming a conductive via extending through the first magnetic core.

4. The method of claim 1, wherein said embedding the first capacitor comprises embedding a first stack of one or more capacitive elements in the substrate core, each of the one or more capacitive elements comprising a conductive substrate having a front side and a back side, a dielectric layer on the front side of the conductive substrate, and a conductive polymer layer on the dielectric layer, the conductive polymer layer of each capacitive element being electrically insulated from the conductive substrate of each capacitive element of the first stack, and wherein the output terminal of the first LC module is connected to the conductive substrate of each capacitive element of the first stack.

5. The method of claim 4, wherein the first stack of one or more capacitive elements includes a first capacitive element and a second capacitive element, the back sides of the first and second capacitive elements facing each other with a laminate therebetween.

6. The method of claim 1, wherein the first inductor includes a plurality of inputs for carrying current at different interleaved phases, and said providing the input terminal of the first LC module comprises providing a plurality of input terminals on the first side of the substrate core connected respectively to the plurality of inputs of the first inductor.

7. The method of claim 1, further comprising forming a conductive via though the substrate core and electrically connected to the conductive substrate of each capacitive element of the first stack.

8. The method of claim 1, further comprising:
embedding a second inductor in the substrate core, wherein the first LC module further includes the second inductor, the output terminal of the first LC module is further connected to an output of the second inductor, and the sense terminal is further connected to the output of the second inductor; and
providing a second input terminal of the first LC module on the first side of the substrate core connected to an input of the second inductor.

9. The method of claim 1, further comprising embedding a second capacitor in the substrate core, wherein the first LC module further includes the second capacitor, the output terminal of the first LC module is further connected to an anode of the second capacitor, and the sense terminal is further connected to the anode of the second capacitor.

10. The method of claim 9, further comprising:
embedding a second inductor in the substrate core, wherein the first LC module further includes the second inductor, the output terminal of the first LC module is further connected to an output of the second inductor, and the sense terminal is further connected to the output of the second inductor; and
providing a second input terminal of the first LC module on the first side of the substrate core connected to an input of the second inductor.

11. The method of claim 1, wherein the output terminal of the first LC module is connected to the output of the first inductor and to the anode of the first capacitor via a redistribution layer (RDL).

12. A method of manufacturing a semiconductor device, the method comprising:
embedding a first inductor in a substrate core of a substrate;
embedding a first capacitor in the substrate core, the first inductor and the first capacitor defining a first LC module;
embedding a second inductor in the substrate core;
embedding a second capacitor in the substrate core, the second inductor and the second capacitor defining a second LC module that is electrically isolated from the first LC module;
providing an input terminal of the first LC module on a first side of the substrate core connected to an input of the first inductor, the input terminal of the first LC module being configured to receive an input voltage Vᵢ₁ and an input current Iᵢ₁ that vary with time;
providing an input terminal of the second LC module on the first side of the substrate core connected to an input of the second inductor, the input terminal of the second LC module being configured to receive an input voltage Vᵢ₂ and an input current Iᵢ₂ that vary with time;
providing an output terminal of the first LC module on a second side of the substrate core connected to an output of the first inductor and to an anode of the first capacitor, the output terminal of the first LC module being configured to output an output voltage Vₒ₁ < Vᵢ₁ and an output current Iₒ₁ that vary with time;
providing an output terminal of the second LC module on the second side of the substrate core connected to an output of the second inductor and to an anode of the second capacitor, the output terminal of the second LC module being configured to output an output voltage Vₒ₂ < Vᵢ₂ and an output current Iₒ₂ that vary with time;
providing a first sense terminal on the first side of the substrate core connected to the output of the first inductor and to the anode of the first capacitor, the first sense terminal providing a feedback loop for regulating an output of a prior stage active component;
providing a second sense terminal on the first side of the substrate core connected to the output of the second inductor and to the anode of the second capacitor, the second sense terminal providing a feedback loop for regulating an output of a prior stage active component; and
mounting an integrated circuit die on the substrate such that the first LC module is in alignment with a first power rail of the integrated circuit die and the second LC module is in alignment with a second power rail of the integrated circuit die.

13. The method of claim 12, wherein the first inductor includes a plurality of inputs for carrying current at different interleaved phases, and said providing the input terminal of the first LC module comprises providing a plurality of input terminals on the first side of the substrate core connected respectively to the plurality of inputs of the first inductor.

14. The method of claim 13, wherein the second inductor includes a plurality of inputs for carrying current at different interleaved phases, and said providing the input terminal of the second LC module comprises providing a plurality of input terminals on the first side of the substrate core connected respectively to the plurality of inputs of the second inductor.

15. A method of manufacturing a semiconductor device, the method comprising:
providing a first LC module including a first inductor and a first capacitor;
embedding the first LC module in a substrate core of a substrate;
providing an input terminal of the first LC module on a first side of the substrate core connected to an input of the first inductor, the input terminal of the first LC module being configured to receive an input voltage Vᵢ and an input current Iᵢ that vary with time;
providing an output terminal of the first LC module on a second side of the substrate core connected to an output of the first inductor and to an anode of the first capacitor, the output terminal of the first LC module being configured to output an output voltage Vₒ < Vᵢ and an output current Iₒ that vary with time;
providing a sense terminal on the first side of the substrate core connected to the output of the first inductor and to the anode of the first capacitor, the sense terminal providing a feedback loop for regulating an output of a prior stage active component; and
mounting an integrated circuit die on the substrate such that the first LC module is in alignment with a first power rail of the integrated circuit die.

16. The method of claim 15, wherein the first inductor includes a plurality of inputs for carrying current at different interleaved phases, and said providing the input terminal of the first LC module comprises providing a plurality of input terminals on the first side of the substrate core connected respectively to the plurality of inputs of the first inductor.

17. The method of claim 15, wherein said providing the first LC module includes encapsulating the first inductor and the first capacitor with a polymer to produce an embeddable tile containing the first LC module.

18. The method of claim 15, wherein the substrate is a package substrate.

19. The method of claim 15, wherein the substrate is an interposer.

20. The method of claim 15, wherein the substrate is a printed circuit board (PCB).
